(19) United States
(12) Patent Application Publication
(10) Pub. No.: US 2019/0353919 A1
(43) Pub. Date: Nov. 21, 2019

(54) MULTI-ZONE COLLIMATOR FOR SELECTIVE PVD

(71) Applicant: APPLIED MATERIALS, INC., Santa Clara, CA (US)

(72) Inventors: BENCHERKI MEBARKI, SANTA CLARA, CA (US); JOUNG JOO LEE, SAN JOSE, CA (US); FARZAD HOUSHMAND, Mountain View, CA (US); ANANTHA SUBRAMANI, SAN JOSE, CA (US); KEITH MILLER, MOUNTAIN VIEW, CA (US); XIANMIN TANG, SAN JOSE, CA (US); PRASHANTH KOTHNUR, SAN JOSE, CA (US)

(21) Appl. No.: 16/414,975

(22) Filed: May 17, 2019

Related U.S. Application Data
(60) Provisional application No. 62/674,353, filed on May 21, 2018.

(51) Int. Cl. G02B 27/30; H01J 37/34

(52) U.S. Cl. CPC G02B 27/30; H01J 37/3405

(57) ABSTRACT

Multi-zone collimators and process chambers including multi-zone collimators for use with a multi-zone magnetron source are provided herein. In some embodiments, a multi-zone collimator for use with a multi-zone magnetron source, comprising a first collimator plate, a second collimator plate, wherein a first collimator zone having a first width is formed between the first collimator plate and the second collimator plate; and a third collimator plate, wherein a second collimator zone having a second width is formed between the second first collimator plate and the third collimator plate, wherein a length of each of the first, second and third collimator plates are different from each other.

### CROSS-REFERENCE TO RELATED APPLICATIONS

This application claims benefit of U.S. provisional patent application Ser. No. 62/674,353, filed May 21, 2018 which is herein incorporated by reference in its entirety.

### FIELD

Embodiments of the present disclosure generally relate to substrate processing equipment and techniques, and more particularly, to methods and apparatus for depositing materials via physical vapor deposition.

### BACKGROUND

The semiconductor processing industry generally continues to strive for increased uniformity of layers deposited on substrates. For example, with shrinking circuit sizes leading to higher integration of circuits per unit area of the substrate, increased uniformity is generally seen as desired, or required in some applications, in order to maintain satisfactory yields and reduce the cost of fabrication. Various technologies have been developed to deposit layers on substrates in a cost-effective and uniform manner, such as chemical vapor deposition (CVD) or physical vapor deposition (PVD).

However, the inventors have observed that with the drive to produce equipment to deposit more uniformly, certain applications may not be adequately served where purposeful deposition is required that is not symmetric or uniform with respect to the given structures being fabricated on a substrate.

One technique developed to allow the use of PVD or CVD to deposit symmetric or asymmetric thin films on structures formed on a substrate is collimator sputtering. A collimator is a filtering plate positioned between a sputtering source and a substrate. The collimator typically has a uniform thickness and includes a number of passages formed through the thickness. Sputtered material must pass through the collimator on its path from the sputtering source to the substrate. The collimator filters out material that would otherwise strike the workpiece at acute angles exceeding a desired angle.

The actual amount of filtering accomplished by a given collimator depends on the aspect ratio of the passages through the collimator. As such, particles traveling on a path approaching normal to the substrate pass through the collimator and are deposited on the substrate. This allows improved coverage in the bottom of high aspect ratio features.

However, certain problems exist with the use of prior art collimators in conjunction with multi-zone magnetrons. Thicker layers of source material may be deposited in one region of the substrate than in other regions of the substrate. For example, thicker layers may be deposited near the center or the edge of the substrate, depending on the radial positioning of the small magnet. The distribution of material on the substrate may be M-shaped. This phenomenon not only leads to non-uniform deposition across the substrate, but it also leads to non-uniform deposition across high aspect ratio feature sidewalls in certain regions of the substrate as well.

In addition, existing collimators used with multi-zone magnetrons block half of the sputtered material due to space constraints and aspect ratio requirements of the collimator.

Therefore, a need exists for improvements in the uniformity of depositing source materials across a substrate by PVD and CVD techniques.

### SUMMARY

Multi-zone collimators and process chambers including multi-zone collimators for use with a multi-zone magnetron source are provided herein. In some embodiments, a multi-zone collimator for use with a multi-zone magnetron source, comprising a first collimator plate, a second collimator plate, wherein a first collimator zone having a first width is formed between the first collimator plate and the second collimator plate; and a third collimator plate, wherein a second collimator zone having a second width is formed between the second first collimator plate and the third collimator plate, wherein a length of each of the first, second and third collimator plates are different from each other.

In some embodiments, an apparatus for processing substrates using physical vapor deposition (PVD) may include a substrate support configured to support a substrate when disposed thereon; a first PVD source configured to provide a stream of a first material towards a surface of the substrate at a first non-perpendicular angle to the substrate surface; a first target; a first multi-zone magnetron source including at least two magnetic zones formed by at least two magnetic tracks; and a first multi-zone collimator having at least two collimator zones, wherein each respective collimator zone aligns with each respective magnetic zone, wherein the collimator includes a plurality of collimator plates, wherein each collimator zone is formed between two adjacent collimator plates, and wherein the first multi-zone collimator is configured to filter atoms and molecules having incident angles that are not perpendicular to the first target.

In some embodiments, a method for processing substrates using physical vapor deposition (PVD) includes providing a stream of a first material from a first PVD source towards a surface of a substrate at a first non-perpendicular angle to the substrate surface; creating at least two magnetic zones formed by at least two magnetic tracks using a first multi-zone magnetron source; directing the stream of the first material through a first multi-zone collimator having at least two collimator zones, wherein each respective collimator zone aligns with each respective magnetic zone, wherein the collimator includes a plurality of collimator plates, wherein each collimator zone is formed between two adjacent collimator plates; and filtering atoms and molecules from the stream of a first material having incident angles that are not perpendicular to a first target.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a schematic diagram of an apparatus used for PVD deposition of material on substrates in accordance with some embodiments of the present disclosure.

FIG. 2 depicts a bottom view of a collimator that blocks a portion of a target in a multi-zone magnetron process chamber.

FIG. 3A depicts a bottom view of a multi-zone collimator for use with a multi-zone magnetron source in process chamber in accordance with some embodiments of the present disclosure.

FIG. 3B depicts a bottom view of a single zone collimator for use with a multi-zone magnetron source in process chamber in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The inventors have provided methods and apparatus for depositing materials via PVD or CVD of materials at an angle to the substrate (as compared to about 90 degrees to the surface of the substrate). For example, material to be deposited may be provided in a stream of material flux from a PVD source that is provided at a non-normal angle to the substrate. The substrate is scanned, or moved through the stream of material flux to deposit a layer of material on the substrate. The substrate may be scanned multiple times to deposit material to a final thickness. The inventors have further observed that embodiments of the inventive multi-zone collimator described herein, as opposed the used of single-zone collimation, advantageously enhances efficient use of dual-lobe linear magnetron sources, enhances deposition rates and throughputs, and lowers cost per substrate processed.

Furthermore, embodiments of the disclosed methods and apparatus advantageously can be used for fin selective doping and oxidation, selective spacer for a silicon fin, selective sidewall contact (e.g. Ti on Si), asymmetric deposition for tighter end-to-end spacing without extreme ultraviolet (EUV) lithography masks, asymmetric fin stressor for channel mobility, selective etch hard masks, Si fin protection layer, selective barrier deposition for low via R metallization with overhang control, spacer deposition for SAXP, line edge roughness control for etch hard mask, pattern CD, and profile modulation.

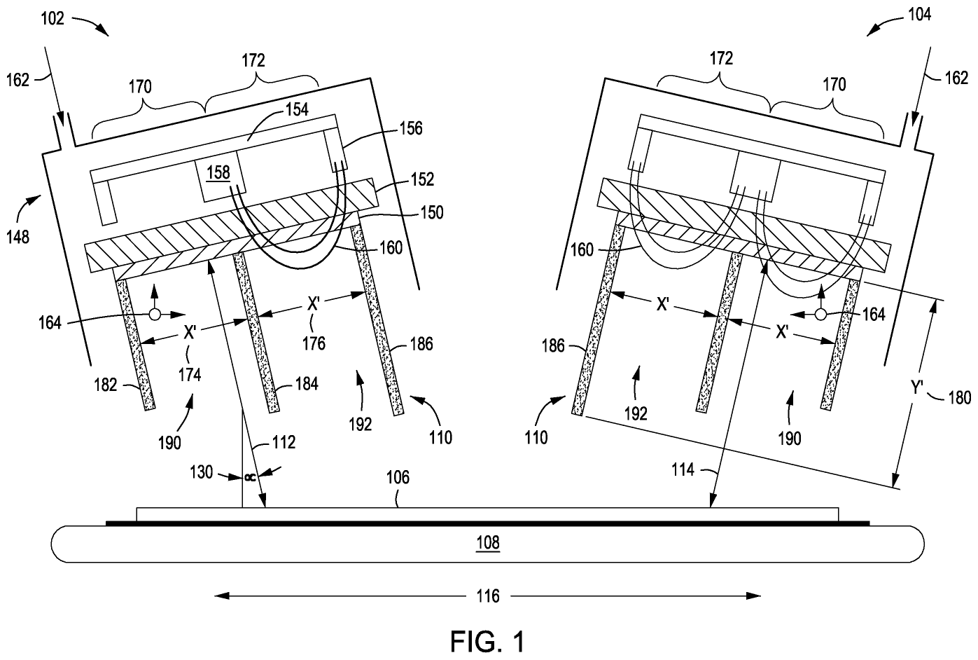

FIG. 1 depicts a schematic diagram of an apparatus used for PVD deposition of material on substrates in accordance with some embodiments of the present disclosure. Specifically, FIG. 1 schematically depicts an apparatus 100 for PVD of materials on a substrate at an angle to the generally planar surface of the substrate. The apparatus 100 generally includes a first PVD source 102, a substrate support 108 for supporting a substrate 106, and a collimator 110. The first PVD source 102 is configured to provide a first directed stream of material flux (stream 112 as depicted in FIG. 1) from the source toward the substrate support 108 (and any substrate 106 disposed on the substrate support 108). In some embodiments, the apparatus 100 includes a second PVD source 104 configured to provide a second directed stream of material flux (stream 114 as depicted in FIG. 1) from the source toward the substrate support 108 (and any substrate 106 disposed on the substrate support 108). The first PVD source 102 is described below in further details and pertains to the second PVD source 104 as well. The substrate support has a support surface to support the substrate such that a working surface of the substrate to be deposited on is exposed to the first stream 112 and second stream 114 of material flux. The substrate support 108 is configured to move linearly (i.e., scan) with respect to the first and second PVD sources 102, 104, as indicated by arrows 116.

The first and second PVD sources 102, 104 include target material to be sputter deposited on the substrate. In some embodiments, the target material of the first and second PVD sources 102, 104 are the same target material. In other embodiments, the target material provided by the first and second PVD sources 102, 104 are different from each other. In some embodiments, the target material can be, for example, a metal, such as titanium, or the like, suitable for depositing titanium (Ti) or titanium nitride (TiN) on the substrate. In some embodiments, the target material can be, for example, silicon, or a silicon-containing compound, suitable for depositing silicon (Si), silicon nitride (SiN), silicon oxynitride (SiON), or the like on the substrate. Other materials may suitably be used as well in accordance with the teachings provided herein. The linear PVD source 102 further includes, or is coupled to, a power source to provide suitable power for forming a plasma proximate the target material and for sputtering atoms off of the target material. The power source can be either or both of a DC or an RF power source.

In some embodiments, unlike an ion beam or other ion source, the first and second PVD sources 102, 104 are configured to provide mostly neutrals and few ions of the target material. As such, a plasma may be formed having a sufficiently low density to avoid ionizing too many of the sputtered atoms of target material. For example, for a 300 mm diameter wafer as the substrate, about 1 to about 20 kW of DC or RF power may be provided. The power or power density applied can be scaled for other size substrates. In addition, other parameters may be controlled to assist in providing mostly neutrals in the streams 112, 114 of material flux. For example, the pressure may be controlled to be sufficiently low so that the mean free path is longer than the general dimensions of an opening of the first and second PVD sources 102, 104 through which the stream of material flux passes toward the substrate support 108 (as discussed in more detail below). In some embodiments, the pressure may be controlled to be about 0.5 to about 5 millitorr.

In embodiments consistent with the present disclosure, the lateral angles of incidence of the first and second streams of material flux can be controlled. For example, FIG. 1 depicts apparatus 100 illustrating material deposition angle 130 of the first stream 112 from the first PVD source 102 in accordance with at least some embodiments of the present disclosure.

The PVD source 102 includes a multi-zone magnetron assembly 148 that creates two or more zones (e.g., a first zone 170 and a second zone 172) of magnetic fields lines 160 for sputtering target material from the target 150. In some embodiments, the magnetron assembly 148 includes at least one target 150, a cathode 152, and a yoke 154 that is used to support a plurality of outer magnets 156 and inner magnets. The plurality of outer magnets 156 and inner magnets create a plurality of magnetic tracks. The magnetic fields generated by the interaction of the inner magnets 158 and the outer magnets 156 create the plurality of magnetic zones for sputtering materials from target 150 when the plasma is generated. The cathode 152 and target 150 are biased to a negative DC bias in the range of about −100 to −600 VDC to attract positive ions 164 of the working gas 162 (e.g., argon) toward the target to sputter the metal atoms. The induced magnetic field from the pair of opposing magnets (e.g., magnets 156, 158) trap electrons 164 and extend the electron lifetime before they are lost to an anodic surface or recombine with gas atoms in the plasma. Due to the extended lifetime, and the need to maintain charge neutrality in the plasma, additional argon ions are attracted into the region adjacent to the magnetron to form there a high-density plasma. Thereby, the sputtering rate is increased. However, the atoms and molecules of sputtered material directed towards the substrate surface come from various angles, and only a comparatively small portion are incident substantially perpendicular to the substrate surface. As a result, it is difficult for sputtering to achieve desired coverage within high aspect ratio steps or contacts (e.g., features) on semiconductor wafer substrate, or to achieve asymmetric deposition of material on the features.

To overcome this drawback, a device known as a collimator 110 is used. In some embodiments, the collimator 110 is a physical structure such as a shroud, disk, or a plurality of baffles that have one or more openings 190, 192 that is interposed between the PVD source 102 and the substrate 106 such that the stream 112 of material flux travels through the structure (e.g., collimator 110). As used herein, the collimator functions as a spread angle control apparatus that controls the angle of the spread of materials being sputtered from the first and/or second PVD sources. Any materials with an angle to great to pass through the openings 190, 192 of the collimator 110 will be blocked, thus limiting the permitted angular range of materials reaching the surface of substrate 106. Thus, the collimator 110 functions effectively as a filter, allowing only the atoms and molecules incident perpendicular to the target 150 to which it is associated with to pass through and coat the substrate 106. However, the width of the openings (e.g., 190, and 192) of collimators are limited by space limitation within the chamber and aspect ratio constraints. That is, the width 174, 176 between plates 182, 184, 186 of the collimator must be within a certain width with respect to the length 180 of the collimator for deposition material scatter reduction. Further compounding this size limitation is that a specified aspect ratio should be maintained. One skilled in the art will readily appreciate that “aspect ratio” is the dimensional ratio of the length or height of the collimator plates in the y-direction relative to the width between the collimator plates in the x-direction. As shown in FIG. 1, the length of each plate 182, 184, 186 in collimator 110 is different, with some plates extending closer to the substrate than others. In some embodiments, as shown in FIG. 1, the longer sides of collimators (i.e., plates 186) should be close to each other, and the substrate should be at an equal distance of all collimator edges.

In addition to uniformity, deposition rate is advantageously improved using the inventive multi-zone collimator described herein. More specifically, uniformity and deposition rates are enhanced by shorter collimator while maintaining aspect ratio for filtration. Since the sputtered species mean free path, which is pressure dependent, remains constant, the shorter collimator plates allows more of the sputtered species to reach substrate enhancing deposition rate.

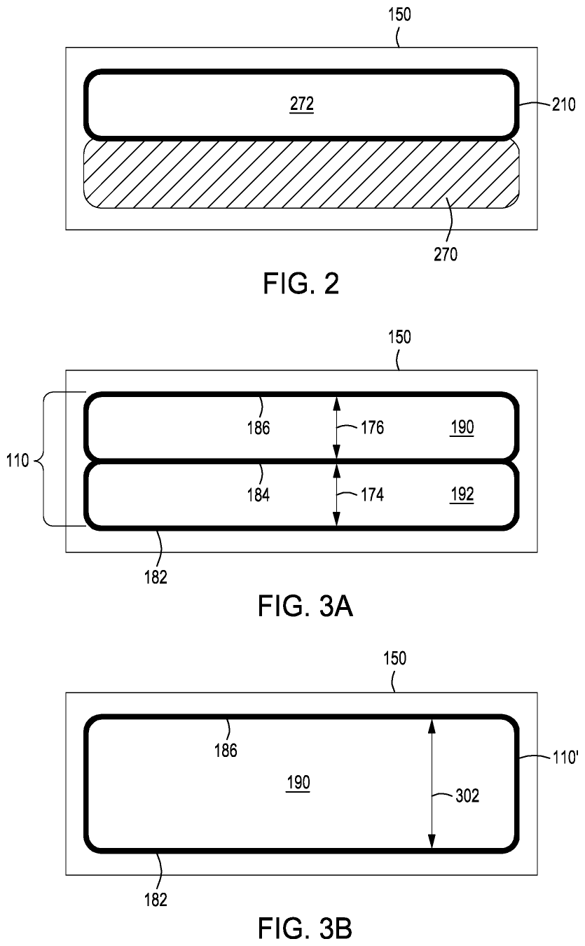

As shown in FIG. 2, typical collimators 210 would block have of the target material being sputtered chambers have multiple zones due to the space and aspect ratio limitations of the collimator. FIG. 2 shows half of target 150 being blocked 270, leaving only the target material in zone 272 available for sputtering on the substrate 106.

Meanwhile, as shown in FIGS. 3A and 3B, the inventive multi-zone collimator 110 allows all of target 150 to be available for sputtering. Specifically, in FIG. 3A, collimator 110 includes two zones 190 and 192 defined by three collimator plates 182, 184 and 186. In some embodiments, if the PVD source 102 includes more than two magnetic tracks/zone 170, 172, the collimator will include as many zones as there are magnetic tracks/zone 170, 172 (e.g., if there are 4 magnetic tracks/zone 170, 172, the collimator will include more plates and have 4 collimator zones.

FIG. 3B includes 1 single collimator zone that covers both magnetic tracks/zone 170, 172. Since the width 302 of the collimator 110′ in FIG. 3B is approximately twice as wide than that shown in FIG. 3A, the length Y′ of the collimator 110′ in FIG. 3B will be approximately twice as long. However, the sputtering rate and uniformity of the embodiments shown in FIG. 3B will not be as good as that of the embodiment shown in FIG. 3A which includes a multi-zone collimator 110.

While the foregoing is directed to embodiments of the present disclosure, other and further embodiments of the disclosure may be devised without departing from the basic scope thereof.

1. A multi-zone collimator for use with a multi-zone magnetron source, comprising:
a first collimator plate;
a second collimator plate, wherein a first collimator zone having a first width is formed between the first collimator plate and the second collimator plate; and
a third collimator plate, wherein a second collimator zone having a second width is formed between the second collimator plate and the third collimator plate,
wherein a length of each of the first, second and third collimator plates are different from each other.

2. The multi-zone collimator of claim 1, wherein the multi-zone collimator is a spread angle control device configured to control an angle of spread of materials being sputtered from one or more material deposition sources.

3. The multi-zone collimator of claim 1, wherein the multi-zone collimator is configured to filter atoms and molecules having incident angles that are not perpendicular to a target to which the multi-zone collimator is associated with.

4. The multi-zone collimator of claim 1, wherein the first and second widths of the multi-zone collimator are limited by space limitation within a process chamber and aspect ratio constraints.

5. The multi-zone collimator of claim 1, wherein the first width is dependent on the length of the first plate.

6. The multi-zone collimator of claim 1, wherein the first width is dependent on the length of the first plate and/or the length of the second plate.

7. The multi-zone collimator of claim 1, wherein the second width is dependent on the length of the third plate.

8. The multi-zone collimator of claim 1, wherein the second width is dependent on the length of the third plate and/or the length of the second plate.

9. The multi-zone collimator of claim 1, wherein an aspect ratio of the length of the first, second and third collimator plates in the y-direction relative to the first and second widths between the collimator plates in the x-direction is constant.

10. The multi-zone collimator of claim 1, wherein a bottom edge the first, second, and third collimator plates of are at an equal distance away from a top surface of a substrate.

11. Apparatus for processing substrates using physical vapor deposition (PVD), comprising:
a substrate support configured to support a substrate when disposed thereon;
a first PVD source configured to provide a stream of a first material towards a surface of the substrate at a first non-perpendicular angle to the substrate surface;
a first target;
a first multi-zone magnetron source including at least two magnetic zones formed by at least two magnetic tracks; and
a first multi-zone collimator having at least two collimator zones, wherein each respective collimator zone aligns with each respective magnetic zone, wherein the collimator includes a plurality of collimator plates, wherein each collimator zone is formed between two adjacent collimator plates, and wherein the first multi-zone collimator is configured to filter atoms and molecules having incident angles that are not perpendicular to the first target.

12. The apparatus of claim 11, wherein the first multi-zone collimator includes:
a first collimator plate;
a second collimator plate, wherein a first collimator zone having a first width is formed between the first collimator plate and the second collimator plate; and
a third collimator plate, wherein a second collimator zone having a second width is formed between the second collimator plate and the third collimator plate,
wherein a length of each of the first, second and third collimator plates are different from each other.

13. The apparatus of claim 12, wherein an aspect ratio of the length of the first, second and third collimator plates in the y-direction relative to the first and second widths between the collimator plates in the x-direction is constant.

14. The apparatus of claim 12, wherein a bottom edge the first, second, and third collimator plates of are at an equal distance away from a top surface of a substrate.

15. The apparatus of claim 11, further comprising:
a second PVD source configured to provide a stream of a second material towards a surface of the substrate at a second non-perpendicular angle to the substrate surface;
a second target;
a second multi-zone magnetron source including at least two magnetic zones formed by at least two magnetic tracks; and
a second multi-zone collimator having at least two collimator zones, wherein each respective collimator zone aligns with each respective magnetic zone, wherein the collimator includes a plurality of collimator plates, wherein each collimator zone is formed between two adjacent collimator plates, and wherein the second multi-zone collimator is configured to filter atoms and molecules having incident angles that are not perpendicular to the second target.

16. The apparatus of claim 15, wherein the second multi-zone collimator includes:
a first collimator plate;
a second collimator plate, wherein a first collimator zone having a first width is formed between the first collimator plate and the second collimator plate; and
a third collimator plate, wherein a second collimator zone having a second width is formed between the second collimator plate and the third collimator plate,
wherein a length of each of the first, second and third collimator plates are different from each other.

17. The apparatus of claim 16, wherein an aspect ratio of the length of the first, second and third collimator plates in the y-direction relative to the first and second widths between the collimator plates in the x-direction is constant.

18. The apparatus of claim 16, wherein a bottom edge the first, second, and third collimator plates of are at an equal distance away from a top surface of a substrate.

19. A method for processing substrates using physical vapor deposition (PVD), comprising:
providing a stream of a first material from a first PVD source towards a surface of a substrate at a first non-perpendicular angle to the substrate surface;
creating at least two magnetic zones formed by at least two magnetic tracks using a first multi-zone magnetron source;
directing the stream of the first material through a first multi-zone collimator having at least two collimator zones, wherein each respective collimator zone aligns with each respective magnetic zone, wherein the collimator includes a plurality of collimator plates, wherein each collimator zone is formed between two adjacent collimator plates; and
filtering atoms and molecules from the stream of a first material having incident angles that are not perpendicular to a first target.

20. The method of claim 19, wherein the first multi-zone collimator includes:
a first collimator plate;
a second collimator plate, wherein a first collimator zone having a first width is formed between the first collimator plate and the second collimator plate; and
a third collimator plate, wherein a second collimator zone having a second width is formed between the second collimator plate and the third collimator plate,
wherein a length of each of the first, second and third collimator plates are different from each other, and wherein an aspect ratio of the length of the first, second and third collimator plates in the y-direction relative to the first and second widths between the collimator plates in the x-direction is constant.
